(19) United States
(12) Patent Application Publication
(10) Pub. No.: US 2003/0038363 A1
(43) Pub. Date: Feb. 27, 2003

(54) Semiconductor device and apparatus for manufacturing same

(75) Inventor: Itaru Matsuo, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/197,563

(22) Filed: Jul. 18, 2002

(30) Foreign Application Priority Data
Aug. 22, 2001 (JP) 2001-251447

(51) Int. Cl. H01L 23/34

(52) U.S. Cl. 257/718; 257/727

(57) ABSTRACT

A semiconductor manufacturing apparatus is provided with a cavity-depth adjusting mechanism for moving a movable member relative to a stationary member to adjust the depth of cavities according to the thickness of a package to be molded. The semiconductor manufacturing apparatus is further provided with a material-thickness adjusting mechanism for moving another movable member relative to another stationary member to adjust the level of a lead frame mounting surface according to the thickness of a lead frame to be mounted.

### BACKGROUND OF THE INVENTION

1. Field of the Invention

The present invention relates generally to a semiconductor device and an apparatus for manufacturing the same and, in particular but not exclusively, to the structure of a plurality of units such, for example, as a conveyance unit, a semiconductor sealing mold assembly and the like installed in the apparatus.

2. Description of the Related Art

FIG. 14 depicts a conventional mold assembly for sealing semiconductor devices with a plastic material. The mold assembly shown therein includes a lower mold 100 and an upper mold 102 disposed so as to be vertically movable relative to the lower mold 100. The lower mold 100 has a frame-mounting surface 100a, while the upper mold 102 has a plurality of cavities of a predetermined shape defined at a lower surface thereof confronting the lower mold 100.

In the conventional mold assembly of the above-described construction, one or more lead frames 104 are connected to a plurality of semiconductor devices via bonding wires and placed on the frame-mounting surface 100a of the lower mold 100. The upper mold 102 is then brought into pressure contact with the lower mold 100, and resin-sealing is conducted by forcibly injecting a sealing resin into the cavities 102a through respective runners 106.

FIG. 14 depicts a case where four pair of IC packages 108 are simultaneously molded using a single molding resin for a pair of lead frames 104.

FIGS. 15 to 17 schematically depict an apparatus for manufacturing semiconductor devices to which a plurality of press units can be added. FIG. 15 depicts a material supply and product discharge unit 112 with which a conveyance unit 114 and a press unit 116 are juxtaposed. FIG. 16 depicts a construction wherein a conveyance rail unit 118 and another press unit 116 are provided in addition to the construction of FIG. 15. FIG. 17 depicts a construction wherein two conveyance rail units 118 and two press units 116 are further provided in addition to the construction of FIG. 16.

The material supply and product discharge unit 112 shown in FIGS. 15 to 17 is provided with a frame supply magazine 122 having a plurality of lead frames 124 vertically placed one above another. As shown in FIG. 18, each of the plurality of lead frames 124 is generally conveyed to a predetermined position using a plurality of endless belts 126 and a plurality of pulleys 128. This conveyance system is called “free flow conveyance”.

After the molding, when the upper mold 102 is opened, the IC packages 108 and culls (resin wastes) 110 placed on the lower mold 100 are vacuum lifted and conveyed by a plurality of vacuum or suction pads 132, as shown in FIG. 19.

FIGS. 20 and 21 are schematic perspective views of the constructions as shown in FIGS. 15 and 17, respectively. In the conventional constructions as shown in these figures, resin supply, maintenance and mold replacement are conducted through one side surface, frame supply and product discharge are conducted through another side surface next to the one side surface, and scrap discharge is conducted through one side surface next to the another side surface. That is, because three side surfaces contiguous to one another are used for access and utility services, addition of one or more press units is conducted using the remaining one surface in case of necessity.

Of the prior art constructions discussed above, the structure shown in FIG. 14 requires a capital investment to be made to a new mold assembly because if the IC packages 108 even though similar or identical in plan geometry have varying molding thicknesses or the frames 104 even though similar or identical in plan geometry have varying thicknesses, different mold assemblies are required to accommodate such varying thicknesses.

Japanese Laid-open Patent Publication No. 4-348536 discloses a mold assembly for resin-molding that can be effectively utilized to sealing electronic component parts even though the resin-sealed packages containing such electronic component parts have varying heights that have resulted from a design change. According to this publication, the mold cavity has its cavity depth capable of being changed by adjusting the position of a knock-out pin concurrently defining the cavity bottom by the intervention of selected one of spacers of a varying thickness. This mold assembly is indeed complicated in structure. Also, this publication is silent as to the applicability of the mold assembly to the production with the lead frames of varying thicknesses.

Japanese Laid-open Patent Publication No. 8-57906 discloses the mold assembly in which lead frames are loaded one at a time after the cavity dimensions have been changed, but is silent as to any technology of resin-sealing lead frames of varying thicknesses.

In a semiconductor manufacturing apparatus wherein the number of press units 116 can be adjusted, i.e., increased as shown in FIGS. 15 to 17, the material supply and product discharge unit 112 has a handling capacity that can be tailored to cope with the overall production capability of the maximum expandable number of the press units (for example, 4 units as shown). However, it has been found that if the number of the press units used is smaller than the maximum expandable number, the efficiency of utilization of the space for installation of the expanded press units and in terms of machine costs is not so high.

On the other hand, the molding method has been suggested in which while a mold assembly comprised of upper and lower molds is used along with a plurality of functional units that are separate and independent from each other and that can be utilized in a desired combination, so that the selected functional units can perform their own operations independently from others. See, for example, Japanese Laid-open Patent Publications No. 11-309751 and No. 8-224753. However, no art has yet been developed to increase the efficiency of utilization of the apparatus by coordinating the handling capacity of the material supply and product discharge unit and the production capacity of the press units employed.

In addition, with the free flow conveyance system used in connection with the semiconductor manufacturing apparatus for conveying materials and/or jigs as shown in FIG. 18, objects to be conveyed are apt to be interfered by the presence of joints between an endless belt 126 and pulleys 128 and/or a joint found in guide rails 130 and are not therefore conveyed smoothly and satisfactorily. Also, in the conveyance system for the semiconductor manufacturing apparatus, a number of free flow conveyances take place before the objects are conveyed to a destination, involving an increase in cost.

On the other hand, with a vacuum conveyance apparatus in which a plurality of suction pads 132 are employed, the suction pads 132 are lowered to engage respective surfaces of packages as molded so that the packages can be picked up under vacuum for conveyance (See, for example, Japanese Laid-open Patent Publication No. 10-4105). However, it has often been observed that chips and/or packages are susceptible to cracking. This is particularly true where the objects are a very thin wafer or a thin package.

In addition, since each suction pad 132 is used to press and then suck a cull portion that connects packages 108 together through associated runners 106 after the packages 108 have been molded, the runners 106 are separated from the cull portion under the influence of the pressing force exerted by the respective suction pad 123 and are eventually scattered within the apparatus. In addition, it often occurs that the pressing force may cause gate portions to separate from the packages 108 at a location different from where they ought to be separated, leaving the gate portions to be unremoved completely with the packages consequently exhibiting a bad shape. Yet, the apparatus shown in FIG. 19 requires the separate and independent use of a delivery unit for delivering a material onto the mold assembly and a delivery unit for delivering the frame 104 and the cull portion 110 after the molding operation, resulting in increase of the cost.

Also, as shown in FIGS. 20 and 21, since in addition to opposite side surfaces the units have connecting surfaces for connection with utilities and for providing an access surface for an attendant worker, they cannot be installed in side-by-side fashion except for one side surface, resulting in reduction in efficiency of utilization of a floor space for installation of the apparatus.

### SUMMARY OF THE INVENTION

The present invention has been developed to overcome the above-described disadvantages.

It is accordingly an objective of the present invention to provide a semiconductor manufacturing apparatus provided with a resin-sealing mold assembly wherein a single mold assembly can be used even though the molding thickness and/or the thickness of lead frames vary.

Another objective of the present invention is to provide a semiconductor manufacturing apparatus of the kind referred to above wherein depending on the number of press units connected and the production capacity thereof, the number of material supply and product discharge units that can be connected can be adjusted to maximize the efficient utilization of the space for installation.

A further objective of the present invention is to provide a semiconductor manufacturing apparatus having a highly reliable and inexpensive conveyance system that is capable of smoothly conveying the lead frames or packages without damaging them even though the lead frames are somewhat warped.

Yet another objective of the present invention is to provide highly reliable and inexpensive semiconductor devices.

In accomplishing the above and other objectives, a semiconductor manufacturing apparatus according to the present invention includes a semiconductor sealing mold assembly having upper and lower molds and a cavity formed in at least one of the upper and lower molds, and is characterized in that the distance between a bottom surface of the cavity and a mating surface of one of the upper and lower molds with the other of the upper and lower molds can be varied.

By this construction, even if the molding thickness differs, the same mold assembly can be used, making it possible to provide an efficient mold assembly and an efficient semiconductor manufacturing apparatus.

In another aspect of the present invention, the distance between a lead frame mounting surface and a mating surface of one of the upper and lower molds with the other of the upper and lower molds can be varied. By so doing, even if the thickness of the lead frames differs, the mold assembly can be commonly used, thus enhancing the efficiency of utilization of the mold assembly and resulting in an efficient semiconductor manufacturing apparatus.

In a further aspect of the present invention, a semiconductor manufacturing apparatus includes a first material supply and product discharge unit for supplying a lead frame to be sealed with a resin and for discharging a package after molding, a conveyance unit for conveying the lead frame and the package, and a first press unit having a lower mold and an upper mold for sealing the lead frame with the resin. Furthermore, a desired number of second material supply and product discharge units can be added to the first material supply and product discharge unit, making it possible to enhance the efficiency of utilization of a floor space for installation of the apparatus.

The semiconductor manufacturing apparatus referred to above contributes to the manufacture of highly reliable and inexpensive semiconductor devices.

### BRIEF DESCRIPTION OF THE DRAWINGS

The above and other objectives and features of the present invention will become more apparent from the following description of a preferred embodiment thereof with reference to the accompanying drawings, throughout which like parts are designated by like reference numerals, and wherein:

FIG. 1 is a schematic perspective view of a semiconductor sealing mold assembly according to the present invention;

FIG. 2 is a schematic vertical sectional view of a material-thickness adjusting mechanism mounted in the semiconductor sealing mold assembly of FIG. 1;

FIG. 3 is a schematic vertical sectional view of a cavity-depth adjusting mechanism mounted in the semiconductor sealing mold assembly of FIG. 1;

FIG. 4 is a vertical sectional view of an upper mold to which a spacer is screwed in place of the cavity-depth adjusting mechanism of FIG. 3;

FIG. 5 is a schematic top plan view of a semiconductor manufacturing apparatus according to the present invention;

FIG. 6 is a schematic top plan view of another semiconductor manufacturing apparatus according to the present invention;

FIG. 7 is a schematic top plan view of yet another semiconductor manufacturing apparatus according to the present invention;

FIG. 8 is a schematic perspective view of the semiconductor manufacturing apparatus of FIG. 7;

FIG. 9 is a perspective view of a conveyance shuttle unit mounted in the semiconductor manufacturing apparatus of FIGS. 5 to 7;

FIG. 10 is a schematic exploded perspective view of a conveyance rail unit mounted in the semiconductor manufacturing apparatus of FIGS. 6 and 7;

FIG. 11 is a schematic perspective view of the conveyance shuttle unit when holding molded packages;

FIG. 12 is a side view of a breaking plate when breaking the molded packages;

FIG. 13 is a schematic perspective view of the semiconductor manufacturing apparatus of FIG. 7;

FIG. 14 is a schematic perspective view of a conventional semiconductor sealing mold assembly;

FIG. 15 is a schematic top plan view of a conventional semiconductor manufacturing apparatus;

FIG. 16 is a schematic top plan view of another conventional semiconductor manufacturing apparatus;

FIG. 17 is a schematic top plan view of yet another conventional semiconductor manufacturing apparatus;

FIG. 18 is a frame conveyance system installed in the conventional semiconductor manufacturing apparatus when lead frames are being conveyed from a frame supply magazine;

FIG. 19 is a schematic perspective view of a package conveyance unit having a plurality of vacuum pads and installed in the conventional semiconductor manufacturing apparatus when conveying the molded packages;

FIG. 20 is a schematic perspective view of the semiconductor manufacturing apparatus of FIG. 15; and

FIG. 21 is a schematic perspective view of the semiconductor manufacturing apparatus of FIG. 17.

### DETAILED DESCRIPTION OF THE PREFERRED EMBODIMENTS

This application is based on an application No. 2001-251447 filed Aug. 22, 2001 in Japan, the content of which is herein expressly incorporated by reference in its entirety.

Embodiment 1.

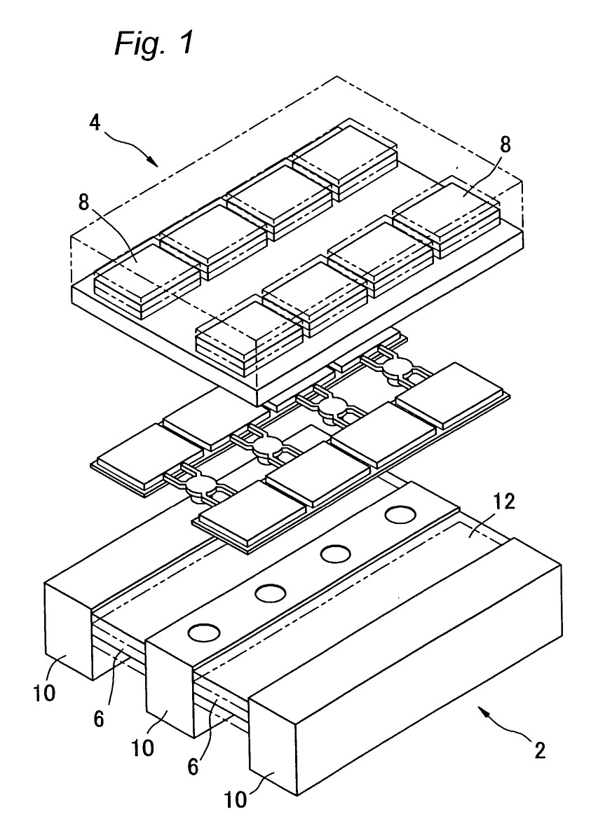

FIG. 1 depicts a mold assembly according to the present invention for sealing semiconductor devices with a plastic material. The mold assembly shown therein includes a lower mold 2 and an upper mold 4 movable up and down relative to the lower mold 2. The lower mold 2 is provided with a material-thickness adjusting mechanism 6, while the upper mold 4 is provided with a cavity-depth adjusting mechanism 8.

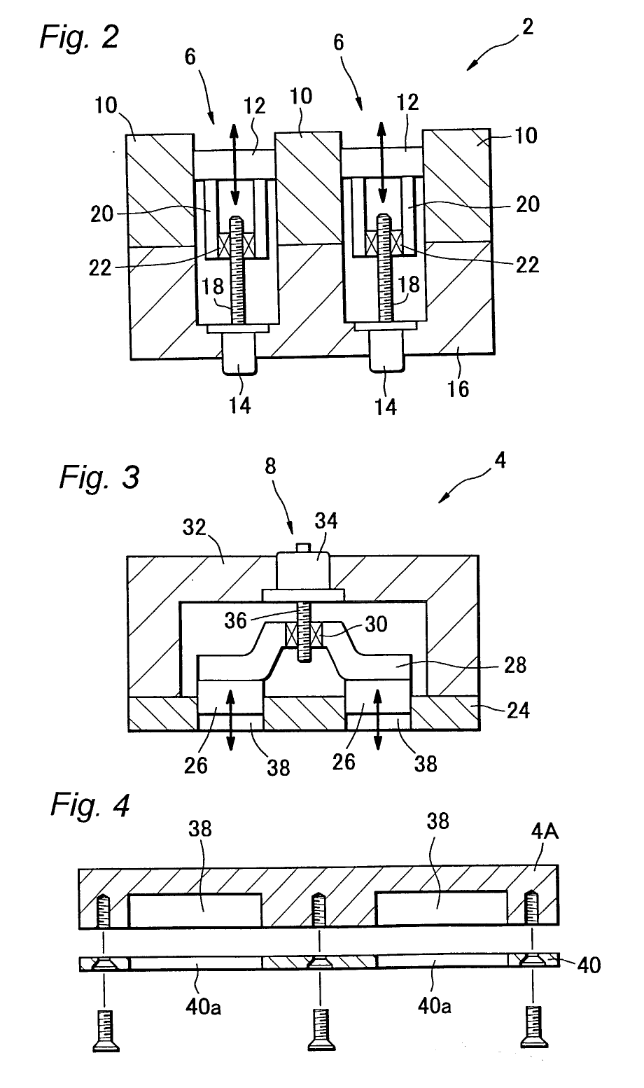

As shown in FIG. 2, the lower mold 2 has a plurality of stationary members 10 disposed at predetermined intervals and a plurality of movable members 12 each disposed between the stationary members 10 so as to be movable up and down relative to the stationary members 10. The stationary members 10 are mounted on a support member 16 on which a plurality of direct drive motors 14 electrically connected to a drive source (not shown) are also mounted. A ball screw 18 is rotatably connected to each motor 14 and is held in mesh with a ball screw nut 22 that is mounted on an associated one of the movable members 12 via a bracket 20. Thus the material-thickness adjusting mechanism 6 is comprised of the movable members 12, direct drive motors 14, ball screws 18, ball screw nuts 22 and the like.

On the other hand, the upper mold 4 has a stationary member 24 and a plurality of movable members 26 mounted on the stationary member 24 at predetermined intervals, as shown in FIG. 3. The movable members 26 are secured to a movable member support 28 having a ball screw nut 30 mounted thereon. A direct drive motor 34 is mounted on a motor support 32, which is in turn secured to the stationary member 24. The ball screw nut 30 is held in mesh with a ball screw 36, which is in turn rotatably connected to the direct drive motor 34. Thus the cavity-depth adjusting mechanism 8 is comprised of the movable members 26, direct drive motor 34, ball screw 36, ball screw nut 30 and the like.

In the mold assembly of the above-described construction, one or more lead frames connected to a plurality of semiconductor devices via bonding wires are placed on the movable members 12 of the lower mold 2. After the upper mold 4 has been brought into pressure contact with the lower mold 2, resin-sealing is conducted by forcibly injecting a sealing resin into cavities 38 through respective gates. After the resin-sealing, packages are released from the upper mold 4 by moving the movable members 26 of the upper mold 4 downwards using the direct drive motor 34.

Because the upper mold 4 has a draft angle of approximately 0 degree, package release is smoothly conducted.

In the above-described construction, the position of the movable members 12 (the distance between the mating surface of the upper mold 4 with the lower mold 2 and the lead frame-mounting surface) can be adjusted by driving the direct drive motors 14 with the drive source, while the position of the movable members 26 (the distance between the mating surface of the upper mold 4 with the lower mold 2 and the bottom surfaces of the cavities) can be also adjusted by driving the direct drive motor 34 with the drive source. Accordingly, even if the thickness of the lead frames placed on the movable members 12 varies or even if the depth of the cavities 38 (the thickness of the packages to be molded) varies, the mold assembly according to the present invention can deal with appropriately.

The depth of the cavities can be changed using an upper mold 4A as shown in FIG. 4 in place of the upper mold 4 of FIG. 3.

More specifically, although the upper mold 4A of FIG. 4 is provided with no cavity-depth adjusting mechanism, a spacer 40 having a plurality of rectangular openings 40a defined therein, which have the same shape (outline) as that of the cavities 38, can be screwed to the lower surface of the upper mold 4A. Accordingly, attaching a spacer 40 of a predetermined depth to the upper mold 4A results in a desired cavity depth.

The upper mold 4A of this configuration, however, must have ejector pins for releasing the packages from the upper mold 4A upon downward movement thereof after the resin-sealing.

It is to be noted here that the cavities may be formed in one of the upper and lower molds or in both of them. In this case, one or both of the upper and lower molds have a draft angle of approximately 0 degree.

It is also to be noted that the spacer 40 may be secured to the lower mold.

Embodiment 2.

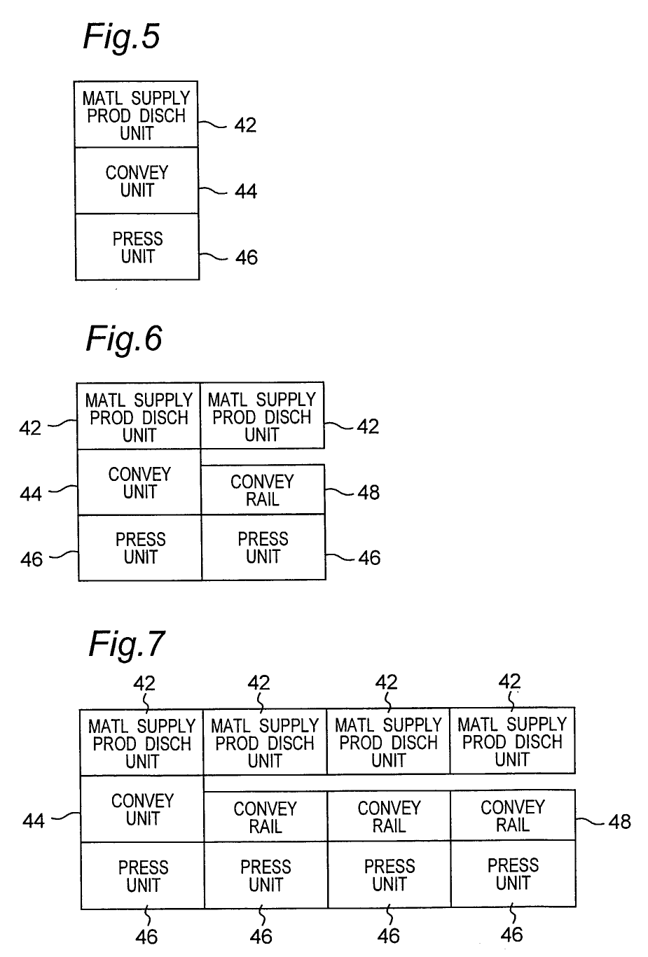

FIGS. 5 to 7 schematically depict an apparatus for manufacturing semiconductor devices to which a plurality of press units can be added. FIG. 5 depicts a material supply and product discharge unit 42 with which a conveyance unit 44 and a press unit 46 are juxtaposed. FIG. 6 depicts a construction wherein another material supply and product discharge unit 42, a conveyance rail unit 48 and another press unit 116 are provided in addition to the construction of FIG. 5. FIG. 7 depicts a construction wherein a combination of two material supply and product discharge units 42, two conveyance rail units 48 and two press units 46 is further provided in addition to the construction of FIG. 6.

The construction according to the present invention can change the number of the material supply and product discharge units 42 in compliance with the number of the press units 46 or the production capacity and, hence, the number of the material supply and product discharge units 42 can be appropriately selected.

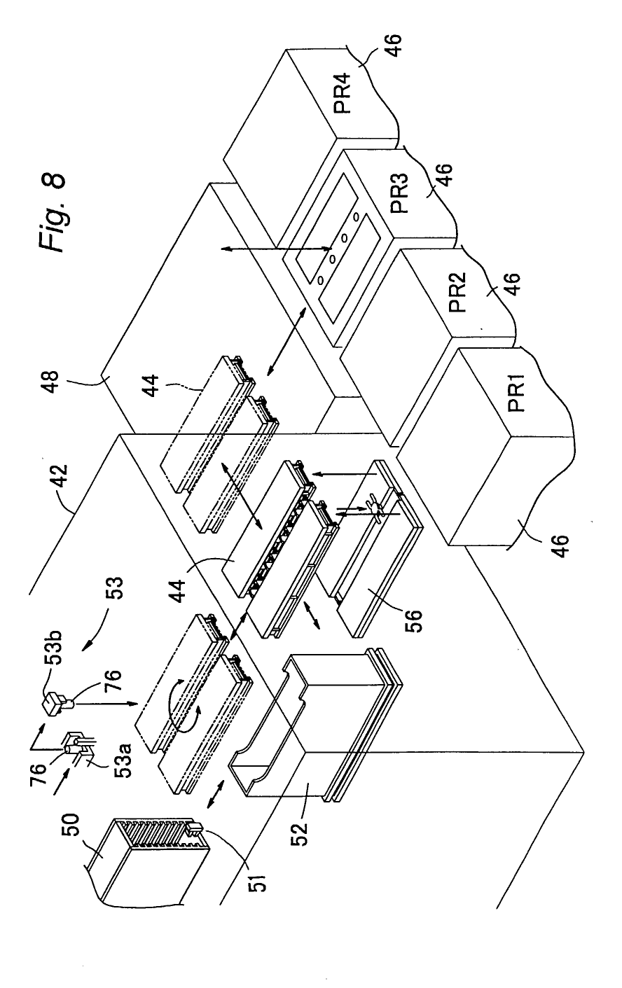

The construction of FIG. 7 is further discussed in detail with reference to FIGS. 8 to 10.

As shown in FIG. 8, the material supply and product discharge unit 42 is provided with a frame supply magazine 50 and a product discharge magazine 52, and a molding resin supply unit 53 is disposed above the material supply and product discharge unit 42.

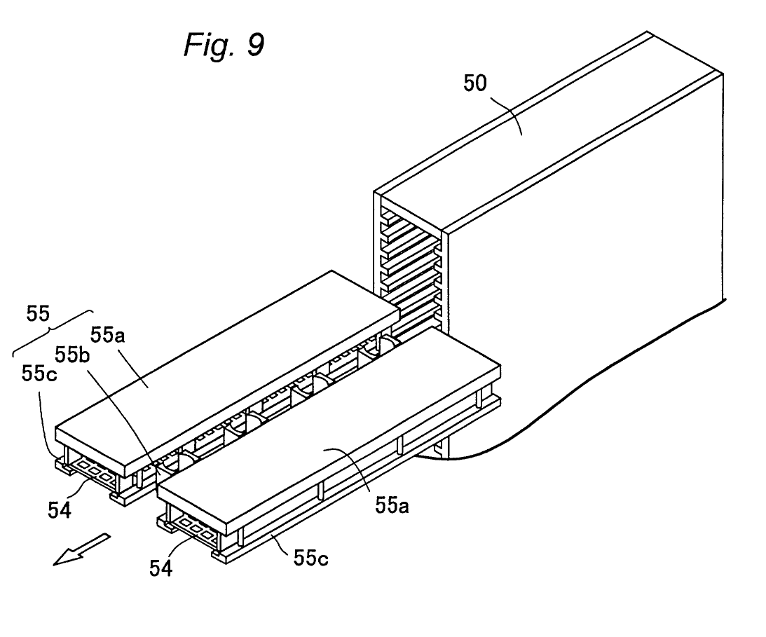

As shown in FIG. 9, the material supply and product discharge unit 42 is further provided with a self-propelled conveyance shuttle unit 55 for conveying lead frames 54 placed on the frame supply magazine 50 to a predetermined position and with a foldable breaking plate 56 for separating culls (resin wastes) from the lead frames after the resin-sealing. The self-propelled conveyance shuttle unit 55 includes two frame holders 55a each for holding a lead frame 54 and a plurality of first chucking means 55b interposed between the two frame holders 55a. Each of the frame holders 55a is provided with a second chucking means 55c.

Furthermore, plural (for example, four) sets of press units 46 are disposed in a line at a position a predetermined distance apart from one surface of the material supply and product discharge unit 42, and a conveyance unit 44 and a conveyance rail unit 48 are disposed between the material supply and product discharge unit 42 and the press units 46.

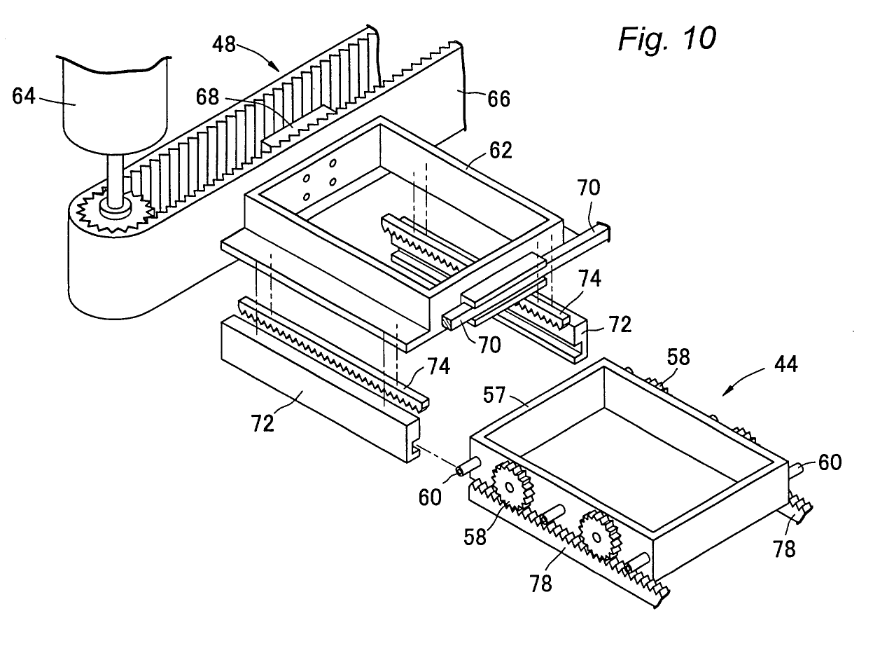

As shown in FIG. 10, the conveyance unit 44 includes a generally rectangular housing 57 having a plurality of pinions 58 rotatably mounted thereon on opposite sides thereof and also having a plurality of cam followers 60 secured thereto on opposite sides thereof.

On the other hand, the conveyance rail unit 48 includes a generally rectangular housing 62 having one side surface that is secured to a portion of a timing belt 66 with a holder plate 68. The timing belt 66 is driven by a servomotor 64. The one side surface of the housing 62 is supported by a linear guide (not shown), and another side surface of the housing 62 opposite to the one side surface is similarly supported by a linear guide 70, along which the housing 62 is conveyed. A pair of spaced side rails 72 extending in a direction perpendicular to the linear guides 70 and each having a cam groove defined therein are secured to a lower surface of the housing 62. Each of the side rails 72 has a rack 74 secured to an inner surface thereof above the cam groove for engagement with the pinions 58 of the conveyance unit 44.

In the semiconductor manufacturing apparatus M of the above-described construction, a plurality of lead frames 54 connected to semiconductor elements (not shown) via bonding wires are first placed vertically at regular intervals on the frame supply magazine 50 installed in the material supply and product discharge unit 42. The conveyance shuttle unit 55 is then moved to and placed on a rotary mechanism (not shown) provided in front of the frame supply magazine 50, and one of the frame holders 55a is positioned with respect to the frame supply magazine 50 so that one of the lead frames 54 placed on the frame supply magazine 50 may be transferred to the second chucking means 55c of one of the frame holders 55a by a slidable pusher 51 shown in FIG. 8.

Thereafter, the conveyance shuttle unit 55 is rotated 180° by the rotary mechanism, while the frame supply magazine 50 is moved downward so that another lead frame 54 may be transferred to the second chucking means 55c of the other frame holder 55a. Furthermore, a plurality of generally cylindrical molding resins 76 placed on a feeder 53a of the molding resin supply unit 53b are clamped one by one by a clamp 53b and successively transferred to the plurality of first chucking means 55b in the conveyance shuttle unit 55.

The conveyance shuttle unit 55 having two lead frames 54 each chucked at opposite sides thereof by the second chucking means 55c and also having a plurality of molding resins 76 clamped by the plurality of first chucking means 55b then travels to a position below the conveyance unit 44 and is chucked by a chucking means (not shown) mounted on the conveyance unit 44. At this moment, the cam followers 60 of the conveyance unit 44 are received in the associated cam grooves in the conveyance rail unit 48, and the pinions 58 of the conveyance unit 44 are held in engagement with the associated racks 74 of the conveyance rail unit 48. Accordingly, while holding the conveyance shuttle unit 55 at a lower portion, the conveyance unit 44 is moved toward the first press unit 46 by driving the pinions 58.

As shown in FIG. 10, each of the press units 46 has two racks 78 spaced at a predetermined interval for engagement with the pinions 58 of the conveyance unit 44. Accordingly, the pinions 58 of the conveyance unit 44, which has been just moved to the first press unit 46, are brought into engagement with the racks 78 of the first press unit 46, and the conveyance unit 44 is conveyed to a predetermined position on the lower mold mounted in the first press unit 46. Then, the conveyance shuttle unit 55 held at a lower portion of the conveyance unit 44 releases chucking of the molding resins 76 by the first chucking means 55b and chucking of the lead frames 54 by the second chucking means 55c, and places the plurality of molding resins 76 and the two lead frames 54 at respective positions on the lower mold.

The conveyance shuttle unit 55, which has just released the molding resins 76 and the lead frames 54, is then conveyed by the conveyance unit 44 to follow, in the opposite direction, the same course which it has followed when supplying the molding resins 76 and the lead frames 54 to the first press unit 46, until the conveyance shuttle unit 55 reaches the frame supply magazine 50.

The conveyance shuttle unit 55 receives again two lead frames 54 and a plurality of generally cylindrical molding resins 76 from the material supply and product discharge unit 42, and is chucked by the chucking means of the conveyance unit 44 held by the conveyance rail unit 48.

Thereafter, the housing 62 of the conveyance rail unit 48 is driven by the servomotor 64 so as to move toward the second press unit 46 along the linear guides 70. Furthermore, when the pinions 58 of the conveyance unit 44 held in engagement with the racks 74 of the conveyance rail unit 48 are driven, they are then brought into engagement with the racks 78 of the second press unit 46. As is the case with the first press unit 46, the plurality of molding resins 76 and the two lead frames 54 are subsequently placed at a predetermined position on the lower mold of the second press unit 46, in the same way as the conveyance to the second press unit 46, a plurality of molding resins 76 and two lead frames 54 are conveyed to the third or fourth press unit 46.

The molding resins 76 conveyed to each of the first to fourth press units 46 melt when the upper mold is moved toward and pressed against the lower mold, and the molten resin is injected into a plurality of cavities through runners and gates. As a result, each of the lead frames 54 placed within the cavities is sealed together with semiconductor elements and bonding wires by the molten resin.

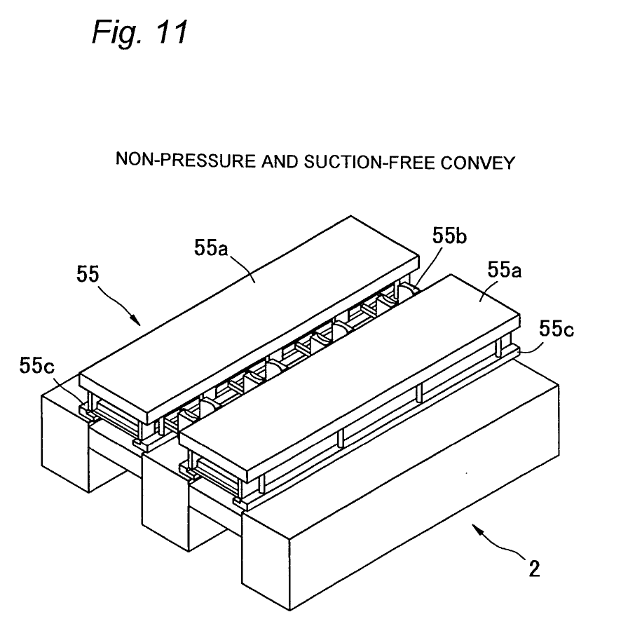

After the resin-sealing, when the upper mold is opened, the conveyance shuttle unit 55 held by the conveyance unit 44 is placed above a plurality of products, i.e., packages (semiconductor devices). Thereafter, as shown in FIG. 11, the packages are held at opposite sides thereof by the second chucking means 55c, while culls are held by the first chucking means 55b. Under such conditions, the packages are conveyed to a position above the breaking plate 56 provided in the material supply and product discharge unit 42.

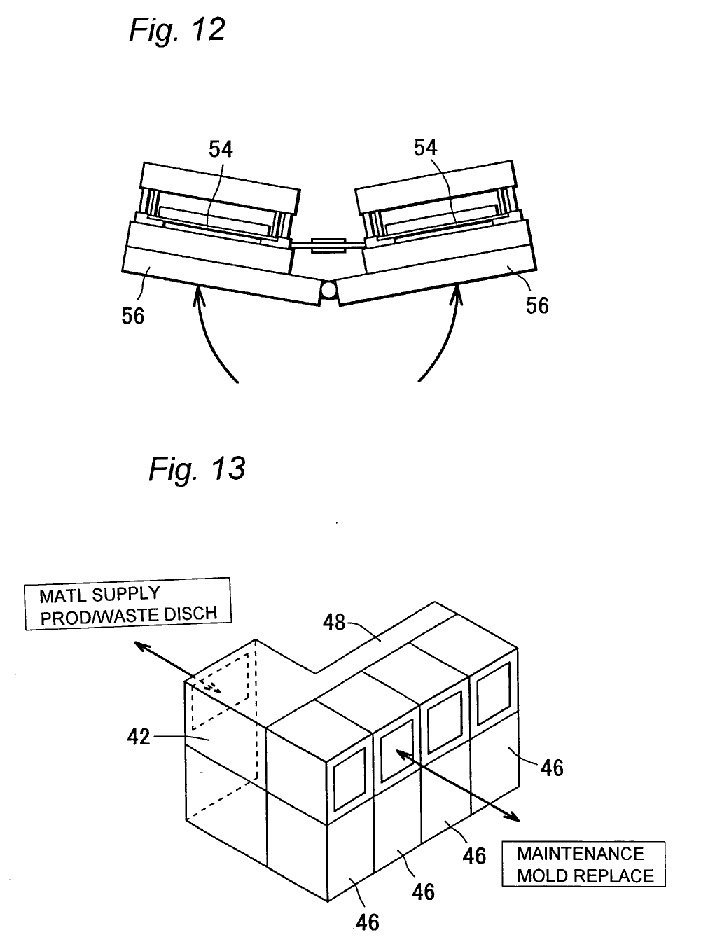

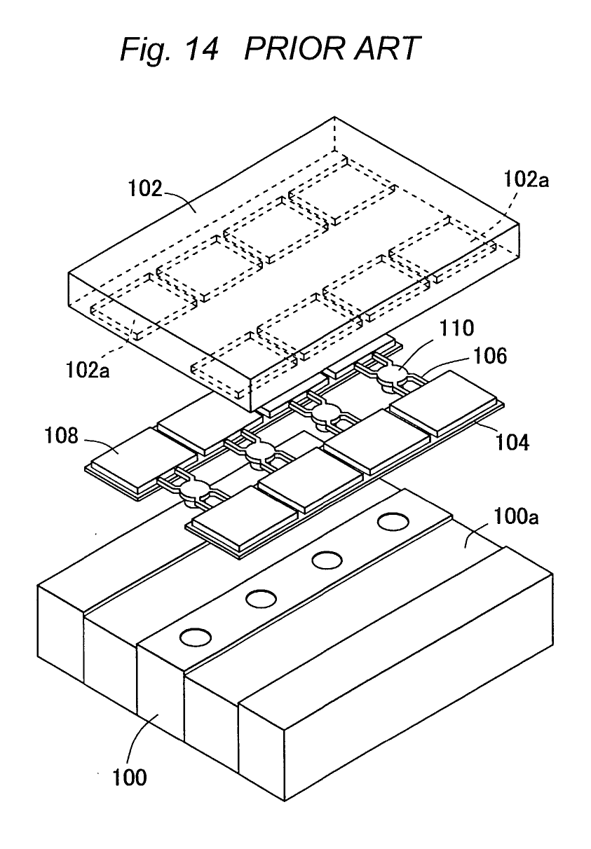

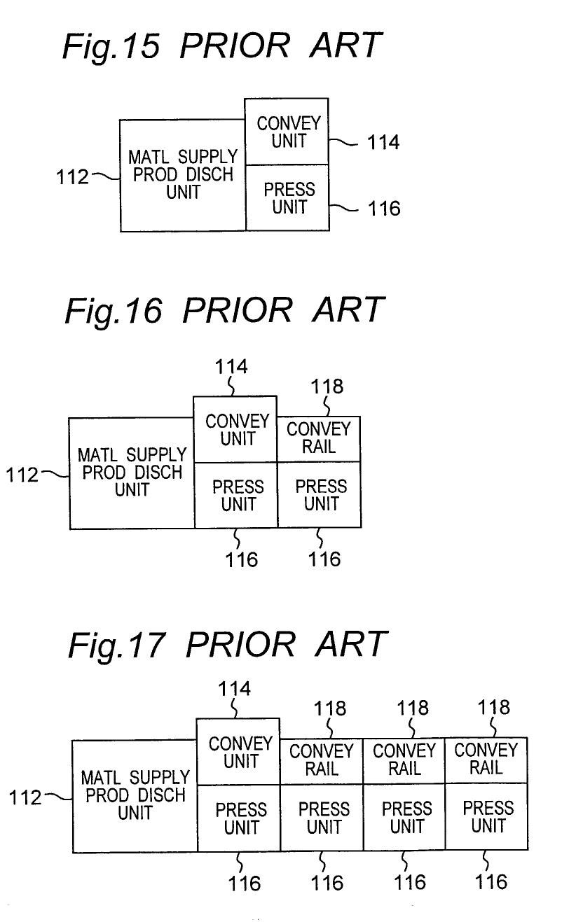

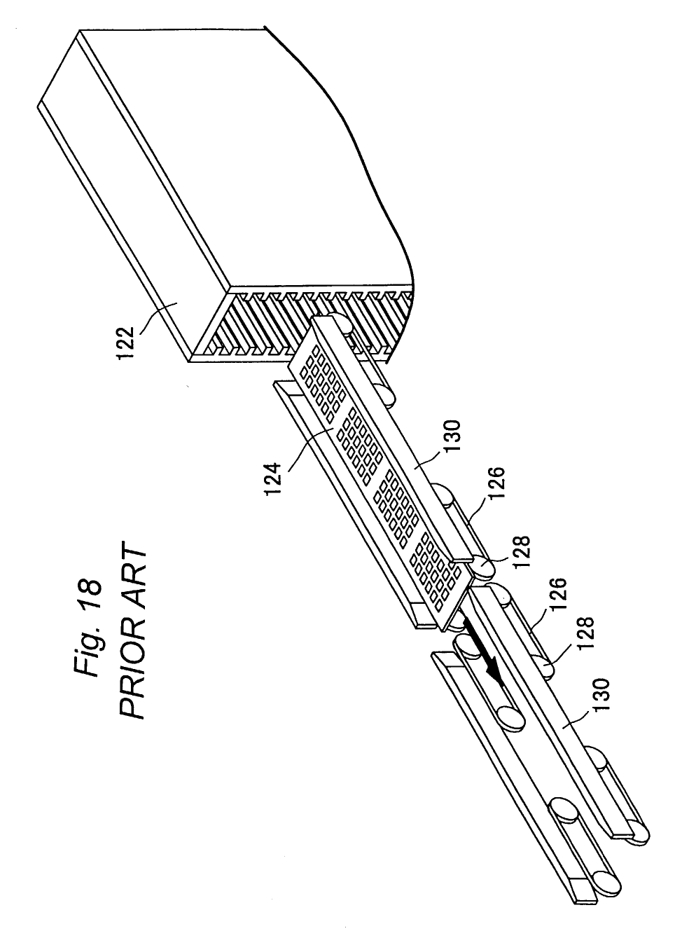

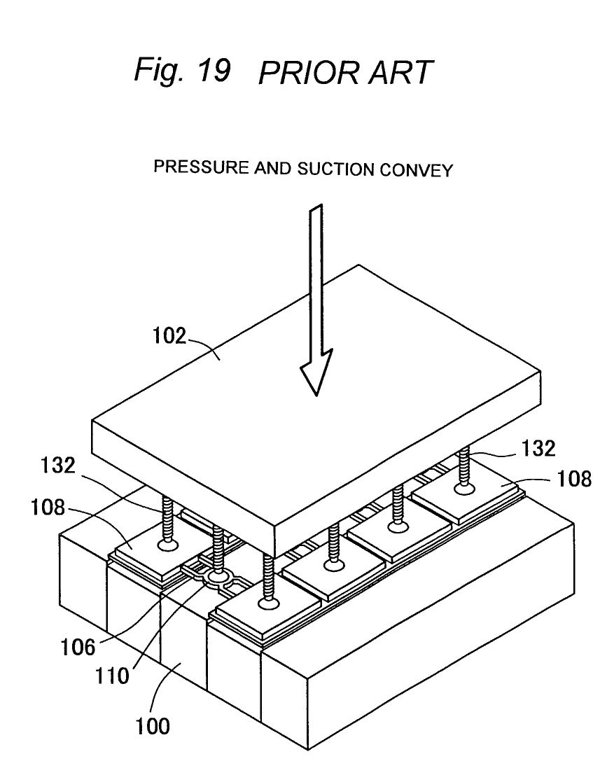

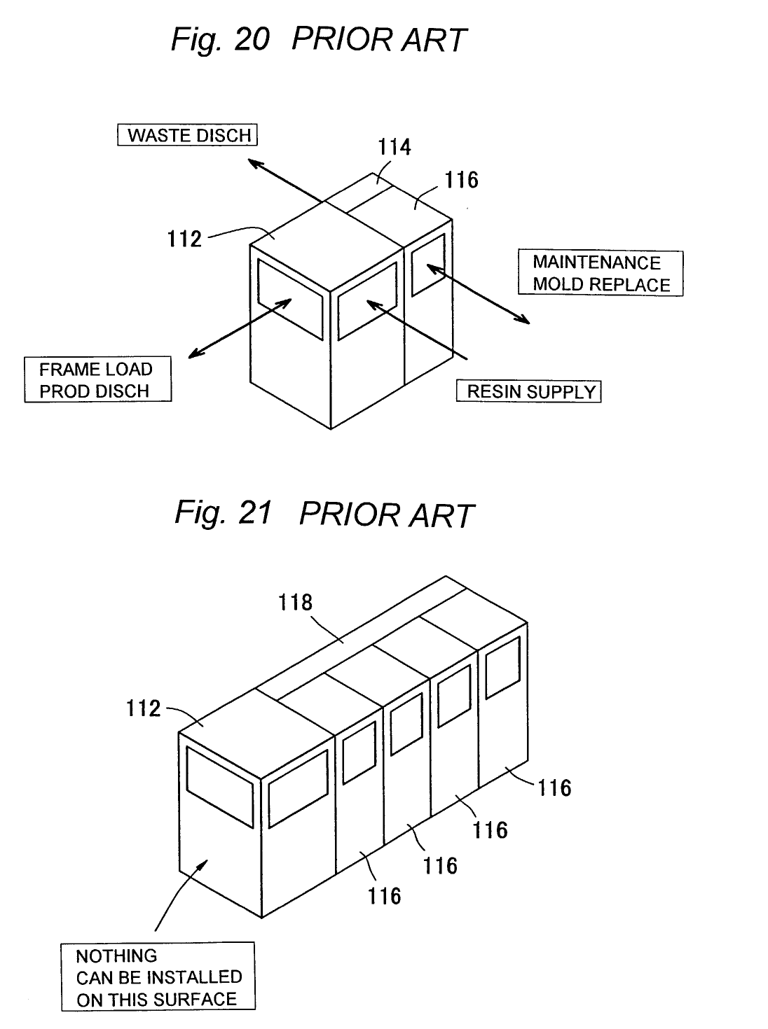

The breaking plate 56 is then lifted, and the packages are placed on the braking plate 56 while they are still held by the second chucking means 55c. Thereafter, as shown in FIG. 12, the breaking plate 56 is folded along a centerline thereof to separate the culls, runners and gates from the packages. Of the packages thus separated, the packaged forming a line are first loaded in the product discharge magazine 52, and upon subsequent rotation of the packages, the packages forming another line are then similarly loaded in the product discharge magazine 52.

As shown in FIG. 13, the semiconductor manufacturing apparatus of the above-described construction has two opposite side surfaces that are not used for access and utility services, and only the other two opposite side surfaces thereof are used for material supply, product or waste discharge, maintenance, mold replacement and the like, making it possible to install a desired number of units adjacent to one another.

Although in the above-described embodiment the semiconductor manufacturing apparatus has been described as having four press units 46, it can have any desired number of press units by appropriately selecting the length of the timing belt 66 and that of the linear guides 70 of the conveyance rail unit 48.

In the case where only one press unit 46 is provided as shown in FIG. 5, no conveyance rail unit is required. In this case, it is sufficient if the side rails 72 having respective cam grooves and the racks 74 associated therewith are provided at predetermined positions so that the conveyance unit 44 may move between the material supply and product discharge unit 42 and the press unit 46.

Although the present invention has been fully described by way of examples with reference to the accompanying drawings, it is to be noted here that various changes and modifications will be apparent to those skilled in the art. Therefore, unless such changes and modifications otherwise depart from the spirit and scope of the present invention, they should be construed as being included therein.

What is claimed is:

1. A semiconductor manufacturing apparatus comprising:
a semiconductor sealing mold assembly having upper and lower molds and a cavity formed in at least one of the upper and lower molds;
wherein a distance between a bottom surface of the cavity and a mating surface of one of the upper and lower molds with the other of the upper and lower molds can be varied.

2. The semiconductor manufacturing apparatus according to claim 1, wherein the upper mold comprises a stationary member, a movable member movable relative to the stationary member, and a cavity-depth adjusting mechanism for moving the movable member, and wherein the cavity-depth adjusting mechanism is operated to adjust the cavity depth by moving the movable member relative to the stationary member according to a thickness of a package to be molded.

3. The semiconductor manufacturing apparatus according to claim 2, wherein the package is released from the upper mold after molding by moving the movable member toward the mating surface of the upper mold with the lower mold using the cavity-depth adjusting mechanism.

4. The semiconductor manufacturing apparatus according to claim 1, further comprising a spacer secured to at least one of the upper and lower molds to adjust a cavity depth according to a thickness of a package to be molded.

5. The semiconductor manufacturing apparatus according to claim 1, wherein at least one of the upper and lower molds has a draft angle of approximately 0 degree.

6. A semiconductor manufacturing apparatus comprising:
a semiconductor sealing mold assembly having upper and lower molds and a cavity formed in at least one of the upper and lower molds;
wherein a distance between a lead frame mounting surface and a mating surface of one of the upper and lower molds with the other of the upper and lower molds can be varied.

7. The semiconductor manufacturing apparatus according to claim 6, wherein the lower mold comprises a stationary member, a movable member having the lead frame mounting surface and being movable relative to the stationary member, and a material-depth adjusting mechanism for moving the movable member, and wherein the material-depth adjusting mechanism is operated to adjust a level of the lead frame mounting surface by moving the movable member relative to the stationary member according to a thickness of a lead frame to be mounted on the lead frame mounting surface.

8. A semiconductor manufacturing apparatus comprising:
a first material supply and product discharge unit for supplying a lead frame to be sealed with a resin and for discharging a package after molding;
a conveyance unit for conveying the lead frame and the package; and
a first press unit having a lower mold and an upper mold for sealing the lead frame with the resin;
wherein a desired number of second material supply and product discharge units can be added to the first material supply and product discharge unit.

9. The semiconductor manufacturing apparatus according to claim 8, wherein a desired number of second press units each having a lower mold and an upper mold can be added to the first press unit, and the number of the second material supply and product discharge units is determined according to the number of the second press units.

10. The semiconductor manufacturing apparatus according to claim 8, wherein only two opposite surfaces thereof are used for access and utility services.

11. The semiconductor manufacturing apparatus according to claim 8, wherein the conveyance unit comprises a chucking means for chucking the lead frame before molding and for chucking the package after the molding.

12. The semiconductor manufacturing apparatus according to claim 8, wherein the conveyance unit comprises a chucking means for chucking culls produced by molding to convey the culls to the first material supply and product discharge unit.

13. The semiconductor manufacturing apparatus according to claim 8, wherein the conveyance unit conveys the lead frame to the lower mold of the first press unit before molding and also conveys the package from the first press unit after the molding.

14. The semiconductor manufacturing apparatus according to claim 8, wherein the conveyance unit directly receives the lead frame placed in the first material supply and product discharge unit and conveys the lead frame to the lower mold of the first press unit.

15. The semiconductor manufacturing apparatus according to claim 8, wherein the conveyance unit holds the package to convey the package from the first press unit after molding, and culls produced by the molding are separated from the package while the package is still held by the conveyance unit.

16. The semiconductor manufacturing apparatus according to claim 15, further comprising a product discharge magazine mounted in the first material supply and product discharge unit, wherein the package is loaded in the product discharge magazine from the conveyance unit after the culls have been separated from the package.

17. A semiconductor device manufactured by a semiconductor manufacturing apparatus according to claim 1.
